(19) United States
(12) Patent Application Publication
(10) Pub. No.: US 2024/0186102 A1
(43) Pub. Date: Jun. 6, 2024

(54) SYSTEM AND METHOD FOR RESOLUTION IMPROVEMENT OF CHARGED PARTICLES MICROSCOPY

(71) Applicant: TECHNION RESEARCH & DEVELOPMENT FOUNDATION LIMITED, Haifa (IL)

(72) Inventors: Raphael DAHAN, Haifa (IL); Ido KAMINER, Haifa (IL); Michael YANNAI, Haifa (IL); Tal FISHMAN, Haifa (IL)

(21) Appl. No.: 18/410,075

(22) Filed: Jan. 11, 2024

Related U.S. Application Data
(63) Continuation-in-part of application No. PCT/IL2022/050775, filed on Jul. 19, 2022.
(60) Provisional application No. 63/223,805, filed on Jul. 20, 2021.

(51) Int. Cl. H01J 37/147; H01J 37/28

(52) U.S. Cl. CPC H01J 37/147; H01J 37/28

(57) ABSTRACT

A charged particles beam column for inspecting a sample in a sample plane is presented. The charged particles beam column comprises: a charged particles source generating a charged particles beam propagating along a general propagation path towards the sample plane; and at least one charged particles beam shaping unit. The charged particles shaping unit comprises at least one high-frequency electromagnetic radiation generator located in a vicinity of said general propagation path of the charged particles beam and controllably operated to perform synchronized generation of said high-frequency electromagnetic radiation towards at least one interaction region in said general propagation path, to cause interaction between said radiation and the charged particles, thereby directly affecting energy properties of the charged particles passing through said at least one interaction region in the general propagation path and directly affecting spectral resolution of the charged particles beam at said sample plane.

### TECHNOLOGICAL FIELD AND BACKGROUND

The present invention is in the field of charged particles microscopy, in particular electron microscopy, and relates to a method for improving the resolution of an electron microscope.

Electron energy loss spectroscopy (EELS) is a fundamental and widely used technique in electron microscopy. By analyzing the energy spectrum of the electron following interaction with the sample under study, detailed knowledge of the composition, structure and morphology is obtained with nanometer spatial resolution.

However, the energy resolution achievable with EELS is fundamentally limited by the initial electron energy spectrum, prior to interaction with the sample, making certain subtle spectral features unobservable. This limitation, namely electron chromatic aberration, also degrades the obtainable imaging resolution.

Chromatic aberration is commonly mitigated using an electron beam monochromator. According to the common approach, a slit set is used between a set of magnetic prisms. The slit filters a narrow energy band out of the original beam.

### GENERAL DESCRIPTION

There is need in the art for a novel approach for improving the energy resolution of a charged particles microscope, in particular electron microscope. The ability to improve the energy resolution of electron microscopes provides two major advantages: it directly improves electron spectroscopy; and it reduces chromatic aberrations and thus improves the spatial resolution.

The limitations due to electron energy spread are especially severe in low-voltage scanning electron microscopy (LV-SEM) which is extensively deployed as a critical-dimensions analysis tool (referred to as CD-SEM) in the semiconductor industry; high-resolution transmission electron microscopy (HR-TEM) that have an ever-growing importance in the life sciences; ultra-fast TEM (UTEM) that is utilized to measure ultrafast dynamical phenomena ranging from microsecond down to the femtosecond and even the attosecond scale. The invention provides for a novel configuration of a charged particles beam column, a modified charged particles beam column, capable of providing improved energy resolution while avoiding degradation of the electron beam and avoiding a need for a huge and expensive microscope configuration (like the known solution based on the use of electron beam monochromator).

The novel charge particles' monochromator technology of the present invention is lossless, cost-effective, and modular. It can be advantageously utilized in any charged particles beam column without significant modifications.

More specifically, the present invention can be used in electron microscopy and is therefore described below with respect to this specific application. Also, more specifically, the present invention utilizes the interaction of an electron beam with pulsed THz radiation (that is, an electromagnetic field oscillating at rates in the approximated range 10 GHz to few 10^{th} of THz), and is therefore described below with respect to this specific application. It should, however, be understood that the principles of the invention are not limited to any of these specific configurations.

As described above, an electron beam monochromator (MC) is commonly used to mitigate chromatic aberration. However, in a conventional electron beam monochromator, the energy filtering leads to significant loss of electrons due to their blockage by the slit. Various types of slit based MCs are commonly used, namely, the Wien, Alfa, and Omega monochromators.

FIGS. 1A to 1E present a typical monochromator configuration and the resulting improved image within scanning EM (SEM). FIG. 1A illustrates schematically a SEM including a monochromator MC located below an electron gun (which can typically be either a Schottky emitter, field emission, photo-emission, thermionic emission or in some other configuration), and FIG. 1B shows schematically an example of an Omega type MC, i.e. a filter that uses offset lenses to disperse the electrons laterally according to their energy before they are mechanically blocked by the slit. FIG. 1C shows a typical energy spectrum of 10 keV electrons before (OFF) and after (ON) the filter, demonstrating how the slit filters a narrow energy band out of the original beam. While this approach indeed results in a narrower electron energy spread, it is inherently lossy—the filtering operation reduces the electron flux (FIG. 1B, 90% and more in typical cases). Moreover, the filter introduces additional spatial/angular aberrations. These factors impair the obtainable signal-to-noise ratio (SNR) and limit the device performance. The resulting low SNR can be partially mitigated by increasing the signal integration time, but this, in turn, limits the achievable temporal resolution critical to time-domain imaging applications (e.g., live biological samples or in-situ studies of nano-electronic devices). FIGS. 1D and 1E present an example of the improved spatial resolution of monochromated CD-SEM (Critical Dimension SEM) using omega type monochromator (using two off axis cylindric lenses), in particular, LV-SEM (Low Vacuum SEM) image of a Cu mash with MC off (FIG. 1D) and on (FIG. 1E). However, about 95% of the electron beam is lost in this case. Moreover, in both SEMs and TEMs, the installation and operation of conventional monochromators costs more than 1M$ and is technically challenging to operate.

Thus, the above slit-based approach impairs the obtainable signal-to-noise ratio (because of reduction of the electron flux by a factor of 10 and above), thus limiting device performance. Moreover, the integration of a conventional monochromator is a costly and technically challenging operation. For this reason, only high-end multi-million-dollar systems are fitted with such devices.

According to the present invention, high-frequency electromagnetic radiation (THz radiation) is used to shape the electrons in a microscope and thus improve its resolution in energy and space.

Applying optical or THz radiation to an electron beam in an electron microscope has been proposed. For example, it has been proposed to locate such a THz source outside the electron microscope [Kealhofer, C., Schneider, W., Ehberger, D., Ryabov, A., Krausz, F. and Baum, P., All-optical control and metrology of electron pulses. Science, 352(6284), pp.429-433 (2016)]. According to another technique described in WO 2018/077471, an electromagnetic energy source is located inside a microscope and is configured as a resonator configured such that the electron beam passes therethrough. These techniques couple the electromagnetic radiation to the electron beam utilizing a metal foil or microstructure resonator or bow-tie shaped metal resonator.

According to the present invention, a novel electron microscope is provided being configured as an integral system including a high-frequency electromagnetic radiation source (referred to herein as “THz source”) and an electron beam source. In such integral system, the pulsed THz source operates as an electron beam shaping unit. For example, such a pulsed THz source can be realized in a semiconductor structure, e.g., through the photo-Dember effect. The THz source is located close to and spaced-apart from a general propagation path of the electron beam through an electron beam column towards a sample, and controllably generates THz radiation (high-frequency electromagnetic radiation) towards each of one or more interaction regions in the propagation path. By this, energy properties of the electrons passing through the interaction region in the propagation path are directly affected thereby affecting spectral resolution of the electron beam at the sample.

The above configuration of the electron microscope system of the present invention allows for desired compactness of the microscope, while enabling proper control of the THz source parameters to directly affect spectral resolution of the electron beam (rather than via controlled dispersion and subsequent compression of the electron pulses, which is not a practical solution for a compact microscope), as well as enabling the system operation with reduced operational power of the THz source and providing much higher efficiency and higher flexibility for spatial shaping of the THz pulse.

Electron beam shaping in a microscope is utilized to improve the spectral (energy) and spatial resolution of the electron beam. The beam shaping is performed by electron excitation with pulsed electromagnetic radiation of high frequency, preferably THz radiation (i.e. applying AC field of high frequency electromagnetic radiation).

The so-applied THz radiation compresses the energy span of electrons thus increasing the resolution. More specifically, THz radiation and electron are directed to interact in a certain interaction region (generally in at least one interacting region), while a time delay between the pulsed THz excitation and the electron pulsed flow arrival to the interaction region is controlled to provide optimal temporal overlap between the electron and THz radiation. Such optimal temporal overlap is properly synchronized resulting in a temporal alignment between electron energy profile and THz field profile, such that relatively slower and faster components within the electron profile are aligned with and thus affected by, respectively, stronger and weaker components of the THz field profile. This results in the electron beam compression and thus reduction of the electron energy width.

The inventors have shown that the technique of the invention provides a similar reduction factor of the electron energy width as that of the known monochromator-based solution, while enabling this to be achieved in a relatively small and simple configuration and without losing electrons.

Any electron microscopy device (TEM/SEM) could benefit from the device 5 configuration of the present invention, which allows for sharper electron energy spectra and improved imaging resolution. Moreover, this device could also benefit soft matter and cryogenic electron microscopy, which commonly utilize energy filtering to remove scattered electrons and improve the image contrast. The latter is currently a matter of great interest in biology (e.g., the only way to image viruses is with such microscopes).

More specifically, the present invention can be used in an ultrafast electron microscope (UTEM), where the microscope is configured for pulsed operation, and is exemplified below with respect to this specific application. It should, however, be understood that the principles of the invention are not limited to this specific example of the microscope configuration/operational mode.

Generally, the principles of the present invention may be implemented in a conventional microscope, not necessarily UTEM type. In the UTEM, the electrons are pulsed and synchronized with a laser driving the THz generation. In the conventional microscope, the electrons are emitted at random times. Implementation of the present invention in a conventional microscope can operate as follows:

An external independent THz source can be designed to operate in a pulsed mode where the pulses have a sawtooth temporal profile. In this way, a constant temporal gradient of the THz field is maintained (dE/dt=const.), which is optimal for electron compression regardless of the electron arrival time. Using another scheme, a first interaction of the electrons with an electromagnetic field is used to periodically separate the electron beam into two separate paths. Subsequently, in each path electron bunches are obtained with optimal length for compression. Then, in each path, another electromagnetic field is used to compress the bunches. These two pulses can generally be in opposite phases with one another. Finally, a fourth pulse is used to collect the two pulsed and compressed beams back to the microscope original path.

The inventors have developed an improved (simpler) scheme, according to which only two locations/points of electron interaction with external electromagnetic field is provided. This technique utilizes pre-shaping of electron beam being emitted by turning the initial CW electron beam flow into pulses by interaction with continuous radiofrequency (RF) field which modulates the beam current. During further free-space propagation the beam is separated into bunches that enter an interaction region with THz field (monochromator).

Thus, the present invention provides for use of synchronized THz radiation to compress the electron pulse for any device that uses electron imaging, rather than the traditional use of energy filtering that reduces the electron current/flux drastically in addition of being highly expensive. The novel electron microscope system of the invention presents no loss to the electron beam. The energy components constituting the electron wavepacket are compressed by the oscillatory THz field, as opposed to lossy energy filtering with the conventional technique. Implementing the configuration and operation of the present invention is considerably cheaper than the traditional. Since the configuration of the present invention does not require any special electron optics, and owing to the nature of the electron-THz interaction, the microscope of the present invention is far more robust than the traditional one in both the operation and the response to external disturbances.

Thus, according to a broad aspect of the invention, there is provided a charged particles beam column for inspecting a sample comprising: a charged particles source generating a charged particles beam propagating along a general propagation path towards a sample plane; and at least one charged particles beam shaping unit comprising at least one high-frequency electromagnetic radiation generator located in a vicinity of said general propagation path of the charged particles beam and controllably operated to perform synchronized generation of said radiation towards at least one interaction region in said general propagation path, to thereby cause interaction between said radiation and the charged particles in said at least one interaction region, thereby directly affecting energy properties of the charged particles passing through said at least one interaction region in the general propagation path and directly affecting spectral resolution of the charged particles beam at said sample plane.

In some embodiments, the charged particles beam column is an electron beam column, of any known configuration, including that of Transmission Electron Microscope (TEM) or Scanning Electron Microscope (SEM) or any of their known configurations including for example also Scanning Transmission Electron Microscope (STEM), ultrafast TEM (UTEM), ultrafast SEM (USEM), as well as LV-SEM, HR-SEM, HR-TEM.

In some embodiments, the high-frequency electromagnetic radiation generator is configured to produce pulsed THz radiation. The THz field (or generally high frequency electromagnetic field) is used to compress the energy-width and spatial distribution of the charged particles pulse. The spatio-temporal shape of the radiation pulse is configured to achieve optimal compression of the charged particles pulse. More specifically, a time delay between the generation of the THz radiation pulse and the electron pulse arrival to the interaction region is controlled to optimize temporal overlap between the charged particle and THz radiation in the interaction region. The electromagnetic pulse spectral content is controlled. Preferably the frequency of the radiation is substantially of the same size as the electron initial time duration.

In some embodiments, the high frequency radiation generator comprises a semiconductor structure configured to generate the radiation based on the photo-Dember effect or on optical rectification effect.

Generally, any known suitable configuration of a high frequency radiation generator capable of generating THz radiation with varying efficiency can be used.

In some embodiments, the high frequency radiation generator comprises an array of radiation sources producing said radiation towards a plurality of interaction regions along the general propagation path of the charged particles beam.

In some embodiments, the charged particles beam column further comprises a pre-shaping assembly accommodated at the output of the charged particles beam source. The pre-shaping assembly is configured and operable to tune the charged particles beam flow having initial continuous wave form into pulses propagating towards said at least one interaction region.

According to another broad aspect of the invention, it provides a monochromator configured for integration in a charged particles beam column for inspecting a sample in a sample plane. The monochromator comprises at least one charged particles beam shaping unit comprising at least one high-frequency electromagnetic radiation generator located in a vicinity of a general propagation path of a charged particles beam emitted by a charged particles source, each of said at least one high-frequency electromagnetic radiation generator being configured and controllably operable to perform synchronized generation of said high-frequency electromagnetic radiation towards an interaction region in said general propagation path, to cause interaction between said radiation and the charged particles in said interaction region, thereby directly affecting energy properties of the charged particles passing through said at least one interaction region in the general propagation path and directly affecting spectral resolution of the charged particles beam at said sample plane.

According to yet further broad aspect of the invention, it provides a method for controlling inspection of a sample by interaction with a charged particles beam, the method comprising: tuning a charged particles beam flow, having initial continuous wave form, into pulses by interaction of said charged particles beam with RF radiation in a first interaction within a general propagation path of the charged particles beam towards the sample, and affecting energy properties of the pulses of the charged particles beam by interaction with high-frequency electromagnetic radiation in at least one second interaction region within said general propagation path downstream of said first interaction region with respect to a direction of propagation of the charged particles beam along said path towards the sample, thereby directly affecting spectral resolution of the charged particles beam at the sample location of the interaction region in the general propagation path.

### BRIEF DESCRIPTION OF THE DRAWINGS

The patent or application file contains at least one drawing executed in color. Copies of this patent or patent application publication with color drawings will be provided by the Office upon request and payment of the necessary fee.

In order to better understand the subject matter that is disclosed herein and to exemplify how it may be carried out in practice, embodiments will now be described, by way of non-limiting example only, with reference to the accompanying drawings, in which:

FIGS. 1A-1E describe the configuration and operation of the commonly used electron-beam monochromator technology utilizing slit-like filter;

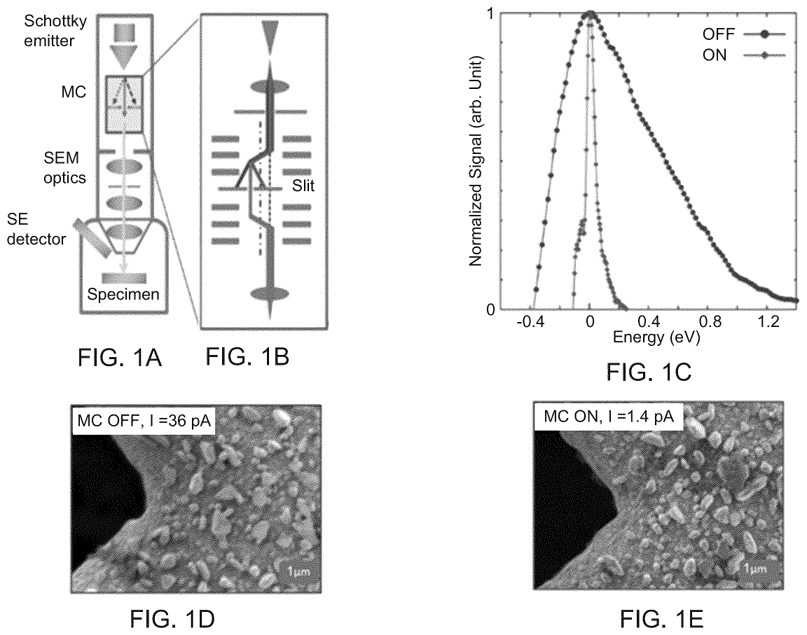

FIG. 2 is a block diagram of a modified electron beam column according to the present invention;

FIGS. 3A and 3B exemplify the integration of a THz generator in an electron microscope (TEM in this example), and the effect of the THz pulses interaction with an electron beam propagating through the microscope;

FIG. 4 show electron beam monochromator using near-field THz radiation: concept and UTEM setup, wherein the right side illustrates the electron energy spectrum (ES) and phase-space distribution (PS) before and after the interaction with the THz pulse (center right panel); and on the left side a UTEM illustration;

FIGS. 5A-5D show the analysis of lossless monochromator operation, wherein FIG. 5A shows electron energy spectra measured without a THz interaction (no compression, black), compared to optimal THz interaction (max compression, red) for 3 electron primary energies; FIGS. 5B and 5C show, respectively, measured and simulated energy spectrum as a function of relative electron-laser delay. The data in FIG. 5A is a cross section of the data in FIG. 5B at the optimal delay (dashed red line in 5B); and FIG. 5D shows an x-y plane map of the electron pulse energy spread (FWHM) at the time delay of optimal energy compression. x=0 marks the sample face (magenta line) and x>0 is free-space;

FIGS. 6A-6B illustrate a method to achieve 3-order of magnitude enhancement in photocurrent by increasing pulse width and rate, wherein FIG. 6A shows the current status; and FIG. 6B shows increased pulse rate and width;

FIG. 7 describes the addition of electron pre-shaping stage using RF modulation for the generation of a pulsed beam that enters the monochromator (MC);

FIG. 8 shows experimental setup of two-point interaction for the electron beam within UTEM for the demonstration of the concept of the present invention; and

FIG. 9 shows a multi-interaction monochromator (MC) to be used in HR-TEM applications enabling an increased compression of the electron energy, using an additional reflector to reflect an input laser beam multiple times to create multiple interactions of the electrons with THz radiation.

### DETAILED DESCRIPTION OF EMBODIMENTS

The charged particle beam microscope (e.g. electron microscope) configured according to the invention performs near-field THz spectroscopy and imaging using free charged particles (electrons) propagation in a charged particles beam column. As mentioned above, more specifically, the present invention can be used in electron microscopy and is therefore exemplified and described below with respect to this specific application.

THz radiation has applications ranging from security and medical imaging to short-range communications. Moreover, it is also attractive for fundamental scientific research, including phase transitions in 2D materials, mobile carrier excitations, and light-induced superconductivity. The generation of THz pulses relies on femtosecond laser pulses in the visible or near-IR that undergo various interactions, involving nonlinear optical processes and solid-state or plasma charge transport. Recent advances in nanophotonics have led to novel approaches in THz generation using metasurfaces. Current studies of ultrafast THz generation mechanisms in nano-scale systems rely primarily on far-field imaging and spectroscopy techniques. However, to reveal details of the underlying physics, it is often necessary to probe the near-field.

The inventors have developed a novel approach for probing THz near-fields: utilizing the ultrafast interaction of free-electron pulses and pulsed THz radiation in close proximity to the source in the so-called nearfield regime.

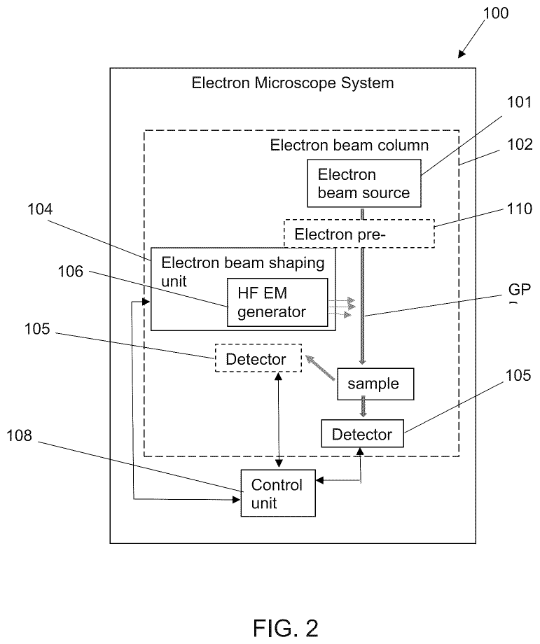

Reference is made to FIG. 2 illustrating, by way of a block diagram, an electron microscope system 100 according to the invention. The system 100 is configured as an integral electron microscope system including an electron beam column 102 and at least one electron beam shaping unit 104 configured according to the principles of the present invention. In the integral system configuration of the present invention, electrons interact, in at least one interaction region 15, with the THz field, generated in-situ in the electron beam column, to compress the electron energy spread.

The system of the invention can be configured as a modified electron microscope, incorporating controllably operated THz radiation generator. The electron beam column 102 typically includes an electron beam source 101 including a cathode (e.g. photocathode) configured and operable to generate an electron beam, beam directing elements (lenses) (not seen in the diagram) for directing the electron beam to propagate along a general propagation path GPP towards a sample (sample plane), and detector(s) 105 for detecting electrons resulting from the electron beam interaction with the sample.

The electron beam shaping unit 104 includes a generator of high-frequency electromagnetic radiation 106, e.g., THz radiation generator, selectively producing THz field pulses towards a region (e.g., interaction region 15) of the general propagation path GPP of the electron beam to controllably induce interaction between the THz radiation and electron beam in said region, i.e., an interaction region (e.g., interaction region 15), located within the general propagation path GPP. The system 100 includes or is associated with a control unit 108, which is configured and operable to control a time delay between the THz pulse generation and the electron pulse arrival to the interaction region 15, to thereby obtain optimal temporal overlap between the electron and THz radiation.

As also shown in the figure, the electron beam source 101 is optionally, but in some embodiments preferably, associated with an electron beam pre-shaper assembly 110. The purpose, as well as configuration and operation of such pre-shaper 110, will be described further below.

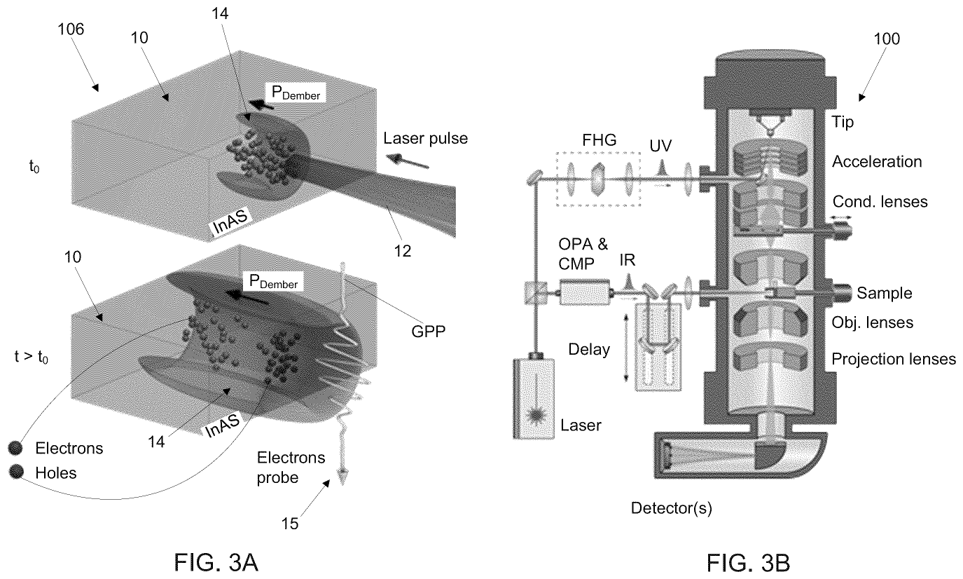

Reference is made to FIGS. 3A and 3B schematically exemplifying the configuration and operation of the THz generator 106 and an effect of the THz pulses interaction with an electron beam propagating through the electron microscope. In the present not limiting example, the invention is implemented in an ultrafast transmission electron microscope (UTEM).

The inventors have demonstrated the use of THz radiation within the electron microscope (e.g. UTEM) for compressing the energy span of the electron pulse and thus increasing the imaging resolution of the microscope. The inventors have experimentally demonstrated lossless monochromation of free-electron pulses, based on their interaction with pulsed single-cycle THz near-fields. To this end, a laser-driven THz emitter (constituting the THz generator) was incorporated near the electron path.

In this connection, reference is made again to FIGS. 3A and 3B. In order to generate the compressing THz radiation, a bulk p-type InAs sample was introduced in the microscope specimen chamber, which generates the compressing THz radiation following pump-laser excitation owing to the Photo-Dember effect (in this non-limiting example). FIG. 3A illustrates operation of THz pulse generation which in this example is performed via the photo-Dember effect, i.e., formation of a charge dipole in the vicinity of a semiconductor surface after ultra-fast photo-generation of charge carriers. Because of the difference of mobilities (or diffusion constants) for holes and electrons and the break of symmetry provided by the semiconductor surface, an effective charge separation occurs in the direction perpendicular to the surface. An electric field is created resulting in that fast carriers (electrons) are slowed, and slow carriers (holes) are accelerated. This effect is present in most semiconductors, but it is particularly strong in narrow-gap semiconductors (mainly arsenides and antimonides) such as InAs and InSb because of their high electron mobility.

In this example, the semiconductor structure 10 is a bulk p-type InAs crystal. Generally, any THz emitting structure, such as semiconductor membranes and nano-wire arrays, can be used to facilitate the direct imaging of THz fields both inside and outside the structure. In this specific example, IR laser pulse (40 μm diameter) impinges on the InAs structure at time to, inducing transient electron and hole currents. Time-delayed electron pulse, at time t>t₀, interacts with the emitted THz radiation.

FIG. 3A illustrates more specifically such effect of generation of THz radiation and its interaction with pulsed electron beam. As shown in FIG. 3A, an 800 nm femtosecond laser pulse 12 impinges upon an InAs crystal 10. The photo-generated electron-hole pairs (blue and red spheres) oscillations serve as a THz pulse source 14. The THz radiation propagates outside the crystal 10 (in free space) towards an interaction region 15 where the THz pulse interacts with an electron beam propagating along a general propagation path GPP.

The sample used in the experiments was prepared from a p-type (10¹⁷ cm⁻³) 500 μm-thick single crystal InAs wafer with (111) growth orientation. A piece from the wafer was manually thinned and polished to 60 μm using standard TEM sample preparation techniques. The thinned crystal was then cleaved along the {110} planes and glued to a TEM copper grid before being mounted on the TEM holder. It should be noted that the inventors have used several different samples in the measurements, and all showed similar behavior.

Thus, as an example, the inventors have demonstrated that where the electron wavepacket passes by the InAs sample, interacting with the emitted THz radiation as shown in FIG. 3A, by controlling the time delay between the pump-laser excitation and electron pulse arrival into the interaction region 15 (i.e., region where the THz radiation propagating outside the crystal reaches the general propagation path of electrons), optimal temporal overlap between the electron and THz radiation is obtained. As a result, the electron energy width is reduced (currently by a factor of 3), achieving the same monochromator effect without losing electrons.

Turning back to FIG. 2, the THz generator unit 106 may include the semiconductor structure located near (in a vicinity of and spaced-apart from) the general propagation path GPP of the electron beam. The THz generator operates such that the semiconductor structure selectively generates pulsed THz radiation towards the interaction region located in the electron beam propagation path GPP. Interaction between the electrons and the THz radiation affects the energy properties of the electrons passing through the interaction region and directly affects spectral resolution of the electron beam at the sample plane.

More specifically, the THz radiation, when applied to the electron beam, compresses the energy span of electrons thus increasing the resolution. A time delay between the pulsed THz excitation and the electron pulsed flow arrival to the interaction region is controlled to provide optimal temporal overlap between the electron and THz radiation, i.e. properly synchronized overlap resulting in a temporal alignment between electron energy profile and THz field profile. As a result, relatively slower and faster components within the electron profile are aligned with and thus affected by, respectively, stronger and weaker components of the THz field profile. This results in the electron beam compression and thus reduction of the electron energy width.

The inventors have studied THz generation processes in the near-field by employing an ultrafast transmission electron microscope (UTEM) schematically illustrated in FIG. 3B. The UTEM uses femtosecond light pulses to excite (pump) a sample and femtosecond electron pulses to measure (probe) the sample's transient state, potentially allowing unprecedented nanometer-femtosecond spatio-temporal resolution. It should be noted that, generally, femtosecond temporal resolution in UTEM is provided by an external femtosecond laser source which is used to pump the sample under inspection.

In the system exemplified in FIG. 3B, the sample whose properties are studied is a structure (e.g., semiconductor structure configured as described above) operable as a THz generator. Hence, such a laser is used to pump the sample which generates the THz field using a separate laser system (depending on the THz pulse generation technique). This is described more specifically further below.

As shown in FIG. 3B, electron beam column includes an electron beam source configured and operable to generate an electron beam propagating along a general propagation path towards a sample plane. Also typically provided in the electron beam column are lenses, as well as one or more detectors (e.g. EELS detector) for detecting electrons resulting from the electron beam interaction with the sample (which is a semiconductor structure in this example operating as THz generator). Also provided in the system shown in FIG. 3B is a light source system which is configured for generating light pulses involved in the THz generation and electron beam generation from a TEM cathode. The light source system includes a laser and light directing optics (beam splitter and mirror) defining UV and IR laser paths. A 1030 nm fs laser pulse is split, by a beam splitter, into two parts. The first part is converted into 800 nm wavelength at 50 fs pulse duration using an optical parametric amplifier (OPA) and a laser pulse compressor (CMP), and subsequently impinges on the THz generator (sample, being the semiconductor structure configured as described above) to thereby induce transient electron and hole currents resulting in generation of the THz radiation. The second part of the laser pulse is converted into UV light via fourth harmonic generation (FHG) and is then guided to the TEM cathode of the electron beam source, creating the electron pulses. The electrons are accelerated to e.g. 80 keV and travel down the column along the general propagation path, grazing the THz generator face and continuing towards the sample to provide the imaging and spectroscopy probe. The pump-probe time delay is controlled by a motorized stage, allowing stroboscopic measurements of fs dynamics. The electron energy spectrum after the interaction is analyzed using an electron energy loss spectrometer (EELS).

More specifically, the experiments were conducted using a JEOL 2100 Plus transmission electron microscope (TEM) equipped with a LaB₆ electron gun and driven by femtosecond laser pulses, thus operating as an ultrafast transmission electron microscope (UTEM). The pump and probe pulses are created by a 1030 nm, ˜220 fs laser operating at a 1 MHz repetition rate. Each pulse is split into two: the first pulse is up-converted to UV via two stages of second-harmonic generation and then guided to the TEM cathode by an aluminum mirror inserted inside the TEM column. This process generates femtosecond electron pulses at the laser repetition rate. The electron pulses are accelerated to varying primary energies (60-200keV) and travel down the TEM column, passing by the vicinity of the sample and providing imaging or spectroscopic information, just as this is done in TEM. The second pulse is converted to 800 nm wavelength and 50 fs pulse duration (FWHM) using an optical parametric amplifier (OPA) and a pulse compressor. This pulse is then used to pump the sample, impinging on it from the side (relative to the electron beam), where the laser spot size is 40 μm FWHM. The time delay between electron-probe and laser-pump pulses was controlled by a motorized stage, thus allowing for stroboscopic measurements of femtosecond dynamics.

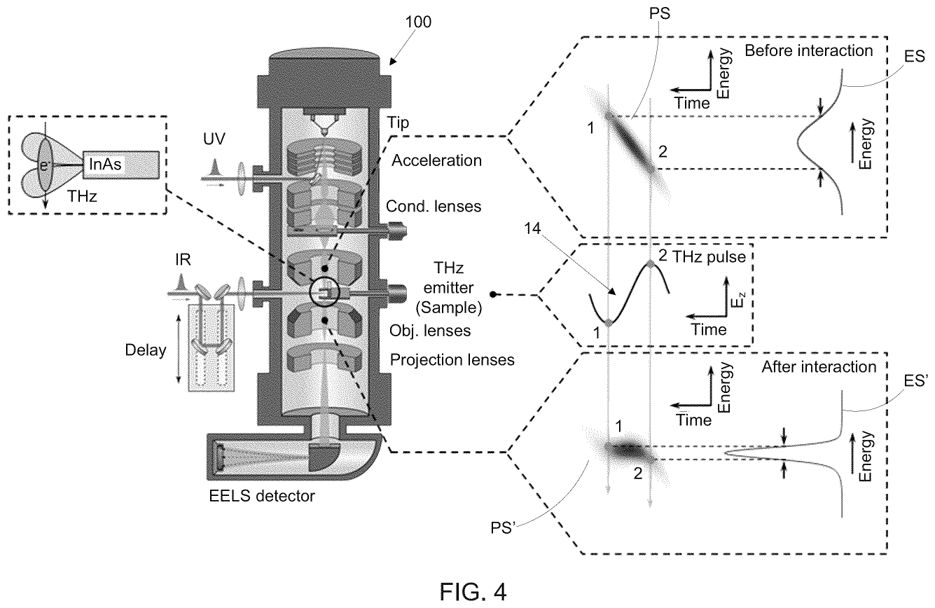

To better understand the energy compression concept, the electron pulse in energy-time phase-space can be considered. In this connection, reference is made to FIG. 4 which illustrates (in energy-time phase space) the pulsed electron beam which interacts with the generated THz radiation such that the late-arriving (low energy) electrons gain energy, and at the same time the early arriving (high energy) electrons lose energy, such that the beam energy spread is reduced. FIG. 4 shows the electron energy spectrum and phase-space distribution (left) ES and PS before interaction with a time-synchronized THz pulse 14 and electron energy spectrum and phase-space distribution ES' and PS' after the interaction with THz pulse 14.

Before the interaction, the electron is dispersed by the acceleration process and the propagation through the column. More specifically, the initial electron pulse (before the compression) has a certain energy and temporal width and is therefore represented by an ellipse PS in phase-space. The phase-space is essentially a graph PS showing when each energy component of the pulse arrives at a certain fixed point in space. Since the more energetic parts of the pulse (e.g., point 1) have a higher velocity, they arrive before the less energetic parts (e.g., point 2). Therefore, the ellipse PS is tilted in phase-space.

The time-dependence of THz pulse 14 can be considered as a sinusoid. Time-synchronized THz pulse 14 interacts with the electron such that different points 1 and 2 in the electron phase-space experience different fields, leading to a narrower energy distribution ES'. More specifically, if the THz pulse 14 is properly synchronized (in space and time) with the electron pulse, point 1 in the initial electron pulse feels a weaker THz field amplitude (Ez) than the later arriving point 2 (opposite sign field). Therefore, the more energetic point 1 feels a decelerating force (exerted by the THz field) while point 2 feels an accelerating one. The result is an overall compression of the electron pulse energy, as indicated by the change in the tilt of ellipse PS' (bottom panel). The energy width ES' is reduced considerably. The dynamics of the electron phase-space distribution is numerically simulated by solving the Vlasov equation (as described below).

The above experiment was conducted in order to analyze the electron (kinetic energy) spectrum after interaction with the THz emitter. For this purpose, a post-column EELS system is installed in the TEM.

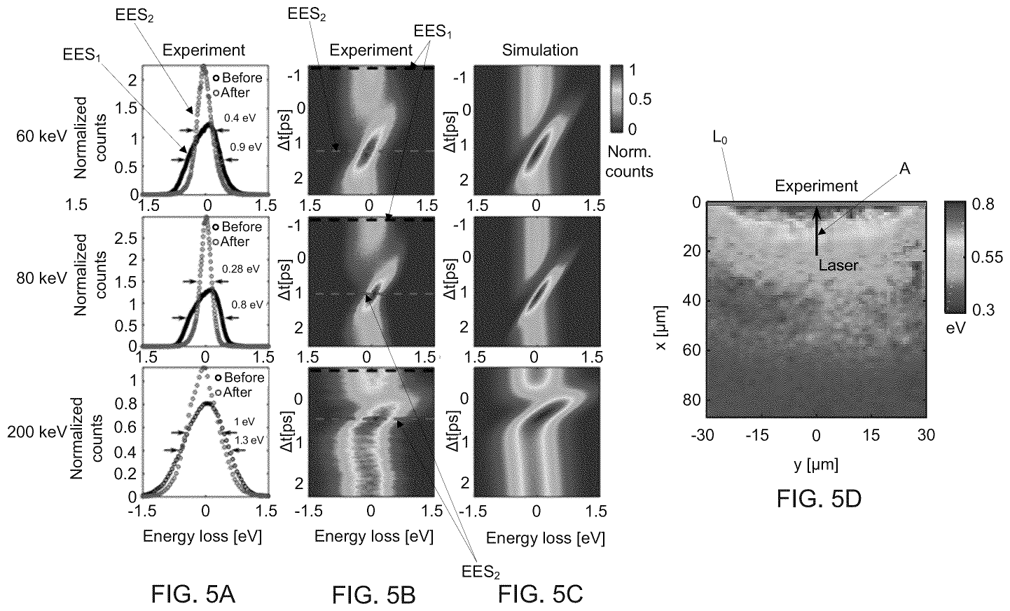

FIG. 5A shows electron energy spectra EES₁ measured without a THz interaction (no compression), compared to optimal THz interaction EES₂ (max compression), illustrating measured electron energy compression. FIGS. 5B and 5C show, respectively, the measured and simulated electron energy spectra versus pump-probe time delay (Δt). The dashed red lines in FIG. 5B correspond to specific optimal Δt at which the electron energy spectra EES₁ and EES₂ in FIG. 5A correspond to. Data in FIGS. 5A to 5C is given for 3 electron primary energies 60 keV, 80 keV and 200 keV.

At the optimal temporal overlap between the electron pulse and the THz pulse (EES₂ data in FIGS. 5A and 5B), the more energetic part of the electron interacts with a decelerating field while the less energetic part interacts with an accelerating one, resulting in a narrower energy distribution. This interaction relies on having a THz field with temporal period similar to the electron-field interaction duration (FIG. 4).

Comparing the electron energy spectra before and at the optimal time delay shows a maximal reduction of the electron energy spread by 2.8-fold for 80 keV electron primary energy (FIG. 5A). Furthermore, integrating over the spectra shows that the total electron count remains constant, proving that this technique is indeed lossless. At different electron primary energies, 60 keV and 200 keV, the effect of longer electron pulse duration (at 60 keV) and less dispersive electrons (at 200 keV) leads to less pronounced monochromation. Theoretical modeling of the monochromation effect is performed using the charge dynamics electron microscopy (CDEM) approach, taking the electron pulse dispersion into account. The theoretical results are in good agreement with the experimental data (FIGS. 5B and 5C).

The EELS data can be captured at each xy (lateral) position within the field of view (FOV) using the built-in scanning TEM (STEM) capability. The inventors have performed experiments with several FOVs and electron spot sizes.

FIG. 5D presents the results acquired with a FOV of 120×120 μm² and an electron lateral spot size of 1 μm FWHM. The STEM electron lens system was tuned to collimate the electron, so it maintained this spot size along the entire length of the interaction region. The inventors used the UTEM to map the change in the electron energy spread across the lateral plane (normal to the electron propagation axis), capturing the data at the time delay which provides optimal energy compression. x=0 marks the sample face (line L₀) and x>0 is free space. The pump laser spot width in the y direction is 40 μm FWHM (significantly smaller than the sample width). Electron primary energy is 80 keV. Arrow A illustrates the pump laser position on the sample face. This result shows the robustness of the technique of the invention, as the interaction occurs in free-space and over a relatively wide region (uniform compression over a 60×60 μm region, 30 μm away from the THz emitter).

The electron energy spread reduction can be explained by considering the electron wavepacket time evolution. As the wavepacket propagates in the microscope column, its slower components arrive at a later time than its faster, more energetic components, thus defining the wavepacket temporal width. By controlling the THz-electron relative time delay, and owing to the oscillatory nature of the THz field, the slower component feels a stronger THz field than the faster one, leading to energy compression of the wavepacket. Importantly, this behavior is weakly dependent on the electron-sample relative orientation and position, making this design extremely robust. Moreover, it is possible to incorporate the THz radiation emitting structure at other positions along the electron beam column (no special electron optics are required), thus freeing the specimen chamber to conduct the desired measurements.

The interaction between the probe-electron and THz field can be theoretically modeled as follows: First, a hydrodynamic model of the photo-Dember effect, which prescribes the transient currents inside the sample is employed. Maxwell's equations are subsequently employed to evaluate the resultant scalar potential in space and time. This potential is incorporated into a time-dependent Schrödinger's equation, using the CDEM formalism to find the dynamics of the electron pulse, and extract the electron energy spectrum versus time delay. The reconstruction of the THz pulse features is done by inverting this theory (it is currently limited by the ˜300 fs electron pulse duration).

Thus, the THz field is used to compress the energy-width of the electron pulse (similar to monochromator concept). According to the invention, the THz field is engineered (its parameters are properly selected) to improve the energy compression. The inventors have shown significant improvement can be obtained by accommodating the THz source inside the microscope.

It should be noted that although in the experiments conducted by the inventors the THz source/generator utilizes the photo-Dember effect in bulk InAs, the principles of the invention are not limited to this specific technology, but rather many other techniques can be used for generating short pulse THz radiation, such as optical rectification, metasurfaces, electro-optical devices (photoconductive antennae, Gunn diodes), etc. Using a stronger THz emitted field and/or better temporal overlap with the electron pulse and/or different THz frequencies can result in higher compression.

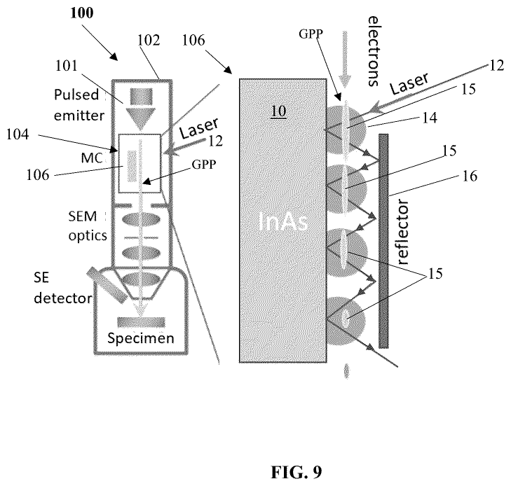

As noted above, the system may be configured to define more than one interaction region. This can be implemented by using more than one beam shaping unit (i.e., THz generators), or by configuring the THz source/generator with an array of THz emitters to manipulate the electron pulse as it propagates inside the microscope, i.e. using a plurality of interaction regions along the general propagation path of the electron beam. More interaction points/regions can give more degrees of freedom and thus better control of the output electron. This will be described more specifically further below with reference to FIG. 9.

It should also be noted that it is possible to use electro-magnetic pulses in frequency ranges other than THz for the same purpose, such as GHz pulses or microwave radiation. The frequency is an important parameter for the compression. In principle, it should be of the same size as the electron initial time duration. Careful control of the electro-magnetic pulse spectral content yields better compression.

The electron pulse and THz field interaction can be used to study THz generation in the near-field of the THz emitter. By scanning the electron position near the THz emitter (in the plane orthogonal to the electron propagation axis) and varying the electron time of arrival, nanometer-femtosecond spatio-temporal mapping of the THz field near the emitter can be obtained. This capability is needed to better understand the physics behind THz generation, and design more efficient THz emitters.

The present invention provides for properly designing the spatio-temporal shape of the THz pulse required to achieve optimal electron compression. This is described more specifically further below. It should be noted that these design considerations should be interpreted broadly, because they describe the interaction of the electron pulse with a general electro-magnetic field under the conditions found in the electron microscope. It is an important generalization of a well-known theory called PINEM (photon induced near-field electron microscopy), which considers only optical frequency electro-magnetic fields.

As described above with reference to FIGS. 5B and 5C, the inventors have shown that the developed simulation (theoretical results) is in good agreement with the experimental results. The inventors have further optimized the theoretical analysis to include the effect of temperature, surface recombination and more. This is described below.

Theoretical modelling of the electron-THz interaction is achieved using the Vlasov equation, which describes the electron dynamics in a one-dimensional phase-space:

∂f/∂t+v∂f/∂z+eE_{z}∂f/∂p_{z}=0. (1)

where f is the electron phase-space distribution function which satisfies the normalization condition:

∫∫f(t,z, p_{z})dzdp_{z}=1,

and the one-dimensional phase-space approximation follows from the paraxiality of the electron in the TEM/SEM. The last term of Eq. (1) represents the Lorentz force applied to the electron by an external electro-magnetic field (e.g., the THz pulse). In this term, the magnetic field contribution has been neglected, which nullifies under the paraxial approximation. By solving Eq. (1) in the time-domain for a given external electric field, the electron phase-space dynamics is obtained, which also yields the corresponding electron energy spectrum.

An alternative approach, which requires less computational effort, avoids the phase-space calculation and computes the electron energy spectrum directly, given that the spectrum observed here can be understood using the classical work done by the fields on a point charge. This theory amounts to (1) calculating the EM fields that act on the impinging electrons, (2) calculating the classical work done on the electron, and (3) averaging over the initial electron distribution to get the statistics of energy loss that is experimentally probed. For the latter, the distribution refers to the electron pulse duration, which determines a variance in the electron arrival time, as well as the electron energy width, which broadens the measured energy spectrum.

In order to evaluate the electron energy spectrum, the electric and magnetic fields in the Lorentz force term are first to be found:

F=−e(E+v×B). (2)

Defining the electron trajectory along z as:

s(t)=z₀+v(t−Δt)\hat{z},

the mean electron energy shift is then given by:

Δϵ(Δt)=∫ₜ_{ᵢ}^{t}^{_{f}}F·vdt=∫ₛ_{ᵢ}^{s}^{_{f}}F_{z}ds )3)

where in the rightmost expression, the paraxiality assumption has been applied, implying that the electron velocity is directed exclusively along z. Moreover, under the quasi-static approximation, the magnetic field term in the Lorentz force can be neglected. For instance, in the experiment conducted by the inventors, this approximation is justified because the electron distance from the crystal is considerably smaller than the THz wavelength (x_{electron}≅10 μm <<λ_{THz}≅600 μm). Therefore, the remaining parameter is F_{z}=−eE_{z}.

In the final step of the calculation, the mean electron energy shift Δϵ(Δt) is represented in energy-shift and time-delay space using a sum of delta functions:

$$Δℰ ( Δ t , ℰ ) = {\sum }_{Δ {t}_{i}} δ ( Δ t - Δ {t}_{i} , ℰ - Δ ℰ ( Δ {t}_{i} ) ) .$$

This expression is then convoluted with a kernel in two-dimensional energy-shift and time-delay space—a two-dimensional chirped Gaussian of the form

exp(−aΔt²−2bΔtΔϵ−cΔϵ²),

thus reproducing the EELS spectra observed in the experiment. The chirp b is added here to accommodate for the electron pulse dispersion, resulting from the electron emission process and free-space propagation inside the TEM column.

The magnitude and duration of the THz pulse strongly depends on the carrier lifetime. Whereas carrier lifetime in good enough bulk materials is limited by the intrinsic intra-band recombination radiative process that are not easy to control, surface recombination due to surface defect arising from the inherent crystal edge are relatively easy to treat.

Surface trapes in crystal lower the effective carrier bulk lifetime τ_{bulk} in a complex way. As an example, for nano-tubes the calculation can be simplified to:

$$\frac{1}{τ} = \frac{1}{{τ}_{b u l k}} + \frac{4 S}{d} , \qquad ( 4 )$$

where S if the surface recombination rate, and d is the radius.

It should be noted that by varying the THz pulse parameters, the electron primary energy, and Wehnelt cup bias, can directly affect the electron pulse duration, dispersion, and resulting energy spread. Thus, by selecting proper conditions for the electron-THz interaction, precise control of electron shapes in time and space can be achieved.

The monochromator developed by the inventors is also compatible with the widely spread systems of SEM and TEM that operate with CW electron beams (rather than a pulsed electron beam as in the UTEM system). To this end, the inherent low electron current that is associated with pulsed operation can be overcome.

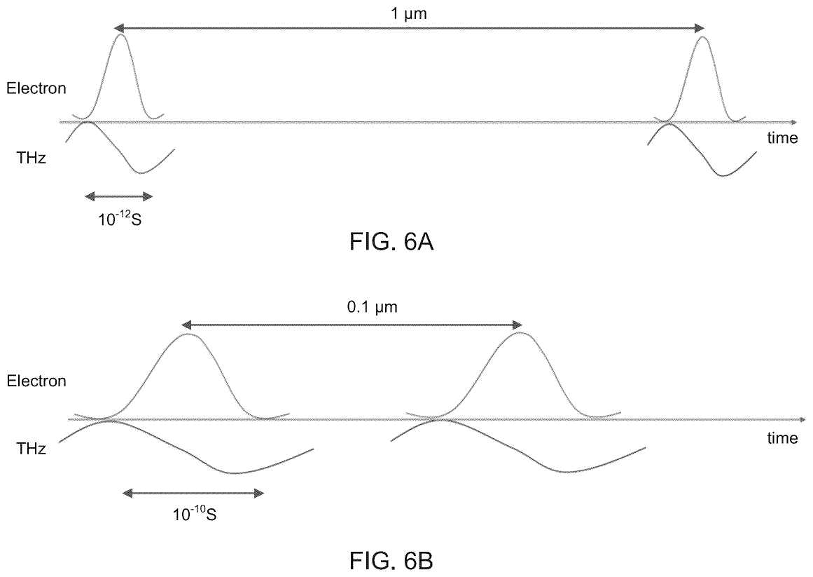

In this connection reference is made to FIGS. 6A and 6B exemplifying the possible solution. More specifically, electron current is to be increased by 3 orders of magnitude. In this example, two independent methods are used: increasing the laser pulse rate to 10 MHz (and thus the separation between pulses is decreased to 0.1 μs, and the total current density increased by a factor of ×10), and making the pulse duration longer by a factor of ×100 and thus achieve the target of ×1000 total increase in the electron current. FIG. 6A shows the current pulse width (˜10⁻¹² s) and rate (1 MHZ), whereas FIG. 6B shows the proposed increase in pulse width (to ˜10⁻¹⁰ s) and decrease in pulse separation (0.1 μs) reflecting a 10-fold increase in pulse rate, providing thus a 3-fold increase in photocurrent. The increase in pulse duration can be achieved by a modification of the carrier life-time mobilities via lower temperatures and lowering surface related recombination processes (as described above).

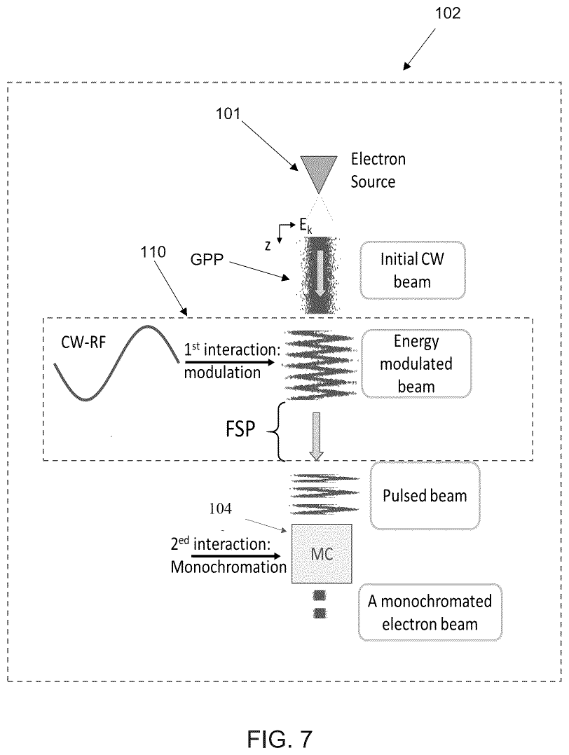

An alternative method that can make the monochromator more compatible with SEMs and TEMs is by performing an electron pre-shaping (110 in FIG. 2). This stage is aimed at turning the initial CW electron beam flow into pulses, and can be implemented by the use of an additional clocking electromagnetic (RF) signal. Reference is made to FIG. 7 exemplifying a part of an electron beam column 102 including an electron beam source 101, a pre-shaping assembly 110 in the electron beam path, and an electron shaping unit 104. Electrons are continuously produced by the source 101, i.e. are continuously emitted (e.g., from a CFEG or a LaB₆ filament), and while propagating along the general propagation path GPP are subjected to interaction (1^{st} interaction) with RF field generated by the pre-shaping assembly 110 (an external RF source) at the first interaction location/point of the general propagation path GPP. This continuous RF (10 MHz-100 GHz) field modulates the beam current. At this first interaction location/point the electron beam energy (and thus velocity) is sinusoidally modulated. Free-space propagation (FSP) separates the beam into bunches that enter further interaction region (second interaction location/point) defined by the monochromator MC of the present invention defined by the electron beam shaping unit 104 including THz radiation generator 106 as described above. An additional option to generate such pulses is by using an optical cavity with a laser drive. As noted above and will be described more specifically further below, the electron beam shaping unit 104 can be configured to define an array of second interaction regions arranged in a spaced-apart relationship along the general propagation path of electrons.

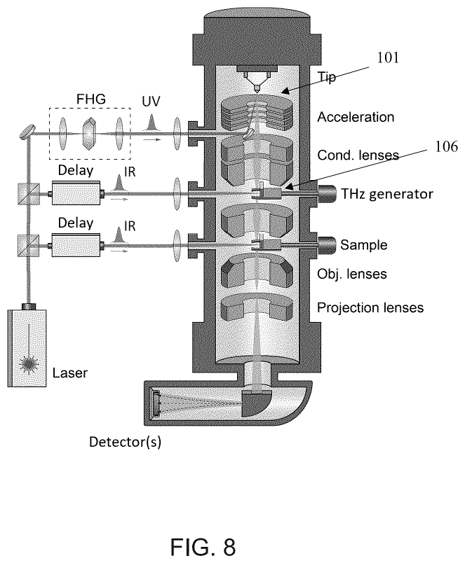

FIG. 8 shows the experimental setup used by the inventors to provide two-point interaction for the electron beam within UTEM. The following should be noted: In this configuration, the electron beam interacts with the IR pulse twice. The first interaction is used to monochromate the electron pulse according to the technique of the present invention as described above. At the second interaction point, downstream, a real sample is located to be studied/inspected using the monochromated beam. It should be noted that the above-described pre-shaping 110 can also be used upstream of said first interaction.

In the following, the inventors introduce a theoretical description of charge-dynamics electron microscopy (CDEM). First, a theory of the interaction of swift electrons with arbitrary classical electromagnetic fields described by a general set of potentials (scalar and vector potentials) is presented. It is shown how CDEM may be described by the same theoretical apparatus which has been successfully applied to describe the interactions of swift electrons with strong optical fields, as used in photon-induced near-field electron microscopy (PINEM). The framework discussed in this section generalizes prior treatments to cases in which the fields are described by both a vector and a scalar potential. Prior work has operated in a gauge in which the scalar potential is eliminated; this is always possible, but in many cases (especially in near-field optics), an approximate description in terms of a pure scalar potential (via Coulomb's law) can prove convenient. Additionally, certain gauges necessarily include a scalar potential, such as the Lorenz gauge, for which a straightforward calculation connects the source terms and the potentials. The inventors employ a general unspecific-gauge approach to derive a master equation for the electron wave function after interacting with the fields created by the studied charge dynamics in the specimen (e.g., such as an irradiated semiconductor producing THz near fields via the photo-Dember effect, as described above in relation to FIG. 3A).

It is shown how this master equation, taken in its classical limit, describes quite accurately the observed energy losses in the CDEM experiments presented above (with reference to FIGS. 5A to 5C). The classical limit of this theory is sufficient when the electron pulse duration is substantially shorter than a single field cycle, so the electron can be treated as a point particle, as is approximately the case in the described experiments. Using the fact that the experiments are well-described by the classical limit of this theory, the inventors then develop a second, complementary theory of CDEM which is purely classical (making no reference to electron wave functions). This second theory will be referred to as the “classical theory of CDEM”. In the classical approach, the observed energy loss is modeled by calculating the work done on a classical point charge (the electron) by the electric force associated with the fields created by the charge dynamics.

In the following, a quantum-mechanical formalism is adopted to describe the interaction of the probe electron with an effective potential Π(r, t) that contains both the vector and scalar potentials. This unified quantum theory can be understood as a generalization of the theory of PINEM to the case of a wide-bandwidth field, such as the THz field in the experiments described here. The unified theory also describes the regimes of so-called anomalous-PINEM. Importantly, all assumptions regarding the free electron used in previous works (e.g., PINEM) on swift-electron interactions with EM fields (e.g., electron paraxiality) are retained here, and are generally applicable in transmission electron microscopy setups. A relativistic free-electron pulse is assumed, with a narrow energy distribution centered around U₀=\sqrt{m²c⁴+h²c²k₀²} and narrow momentum distribution centered around p₀=hk₀\hat{z} (associated with an “unperturbed” rectilinear velocity v). Further assuming that the interaction energy with the electromagnetic field is far smaller than the electron energy U₀=γmc² (“no recoil” approximation), a simple Hamiltonian description of the particle in terms of the effective potential Π may be formulated. To do so, first, the approximate Hamiltonian for an energetic relativistic particle in an external electromagnetic field is written as:

$${H}_{R} \approx {U}_{0} + \frac{{{c}^{2} ( - i ℏ ∇ + e A )}^{2} + {m}^{2} {c}^{4} - {( {U}_{0} + e Φ )}^{2}}{2 ( {U}_{0} + e Φ )} \qquad ( 5 )$$

$$\approx {U}_{0} + \frac{{{c}^{2} ( - i ℏ ∇ + e A )}^{2} + {m}^{2} {c}^{4} - {( {U}_{0} + e Φ )}^{2}}{2 γ m {c}^{2}} ,$$

where the inequality eΦ<<U₀ was used. Expanding the squares and ignoring quadratic terms in Φ and A (as well as identity terms) the following is obtained

$${H}_{R} = \frac{- {ℏ}^{2} {∇}^{2} - 2 ie ℏ A \cdot ∇ + {m}^{2} {c}^{2} - \frac{{U}_{0}^{2}}{{c}^{2}} - \frac{2 {U}_{0} e Φ}{{c}^{2}}}{2 γ m} . \qquad ( 6 )$$

Defining the electron wave function in terms of its envelope as

$$ψ = ϕ {e}^{i {k}_{0} z - \frac{i {U}_{0} t}{ℏ}} ,$$

one finds

iℏ∂ₜϕ=Hϕ, (7)

with H=−iℏv·∇+ev·A−eΦ≡−iℏv·∇+Π, and where

Π(r,t)=ev·A−eΦ. (8)

In deriving this result, the inventors neglected ∇·A (arising from the relation ∇·A/k₀A<<1). Taking the electron wave function to be of the form

$$ψ ( z , t ) ≡ ϕ ( z , t ) {e}^{i {k}_{0} z - \frac{i {U}_{0} t}{ℏ}} ,$$

with Φ(z, t) denoting the envelope wave function, and considering

|k₀ϕ|>>|∇_{ϕ}|=|∂_{z}ϕ|,

(paraxial approximation), the Schrödinger equation may simply be written as

$$( {\partial }_{t} + v {\partial }_{z} ) ϕ ( z , t ) = \frac{1}{i ℏ} Π ( z , t ) ϕ ( z , t ) . \qquad ( 9 )$$

To find this expression, the square root is expanded in powers of ∇ϕ and retained only terms up to the first derivative. Making the standard change of variables z′=z-vt, t′=t, Eq. (9) may be written as

$${\partial }_{{t}^{′}} ϕ = \frac{1}{i ℏ} Π ( {z}^{′} + {vt}^{′} , {t}^{′} ) ϕ , \qquad ( 10 )$$

admitting the solution

$$ϕ ( {z}^{′} , {t}^{′} ) = {ϕ}_{0} ( {z}^{′} ) exp [ - \frac{i}{ℏ} {\int }_{- ∞}^{{t}^{′}} d s Π ( {z}^{′} + vs , s ) ] .$$

Expressed in terms of z, t, this solution can be recast into

$$ϕ ( z , t ) = {ϕ}_{0} ( z - vt ) exp [ - \frac{i}{ℏ} {\int }_{- ∞}^{t} d s Π ( z + v s - v t , s ) ] . \qquad ( 11 )$$

It is important to note that this expression is consistent with previous treatments for which the scalar potential vanishes and then the expression above reduces to (using Eq. (8) for Π)

$$ϕ ( z , t ) = {ϕ}_{0} ( z - vt ) exp [ - \frac{i e v}{ℏ} {\int }_{- ∞}^{t} d s {A}_{z} ( z + v s - vt , s ) ] . \qquad ( 12 )$$

In the CDEM experiment described above A_{z} is equal to zero (see the following section on the hydrodynamic model), and thus it is possible to replace Π by the scalar potential −eΦ (using Eq. (8).

Simulation of the measured EELS data (i.e., electron spectrum versus time-delay) is carried out by first evaluating the Fourier transform of the electron coherent wave function with respect to time at the detector plane, where a time-delay variable Δt is introduced in the incident electron wave function

ϕ₀(z−v·(t+Δt)),

representing the varying pump-probe time-delay in the experiment conducted by the inventors. The squared modulus of this wave function is then convoluted in energy-shift (Δϵ) and time-delay space with an incoherent broadening function—a two-dimensional chirped Gaussian of the form

exp(−aΔt²-2bΔtΔϵ−cΔϵ²).

The chirp b is added here to accommodate for the electron pulse dispersion, resulting from the electron emission process and free-space propagation inside the TEM column.

The inventors have considered a classical limit for the electron wave function after interaction with an arbitrary field, starting from the quantum-mechanical formalism reviewed above and assuming the fields vary negligibly over the duration of the electron pulse. A gauge with no scalar potential can be chosen, allowing to use Eq. (12).

The classical limit is associated with the fact that the electron wave packet duration is shorter than the THz field cycle. In this situation, the electron essentially behaves as a classical point charge. It is then pertinent to Taylor-expand the slowly varying vector potential A_{z}(z-vt+z′, t′) around small values of z-vt, assuming the centroid of the electron wave packet to follow the trajectory z=vt. Thus, the argument of the exponential in Eq. (12) may be expressed as (for the post-interaction electron at t→∞):

$$- \frac{i e}{ℏ} {\int }_{- ∞}^{∞} {vdt}^{′} ( {A}_{z} ( {vt}^{′} , {t}^{′} ) + {\partial }_{{z}^{′}} {A}_{z} ( {z}^{′} , {t}^{′} ) {\vert}_{{z}^{′} = {vt}^{′}} ( z - vt ) + O ( {( z - vt )}^{2} ) ) . \qquad ( 13 )$$

The term independent of z-vt in this expansion contributes an overall phase

$$φ = - ( \frac{e v}{ℏ} ) {\int }_{- ∞}^{∞} {dt}^{′} {A}_{z} ( {vt}^{′} , {t}^{′} )$$

that does not affect the transmitted electron spectrum (energy distribution). Using the relation:

∂ₜA(vt,t)=v∂_{z′}A(z′,t′)|_{z′=vt′;t′=t}+∂_{t′}A(z′,t′)|_{z′=v′;t′=t},

the term linear in z-vt may be expressed as

$$i / ℏ {\int }_{- ∞}^{∞} {vdt}^{′} ( - e {E}_{z} ( {vt}^{′} , {t}^{′} ) ) \cdot ( \frac{z}{v} - t ) .$$

Here, the inventors used E=−∂ₜA, and noted that, for a finite-duration field, the boundary term associated with the integral of ∂_{t′}A vanishes. The integral over t′ simply represents the work done on the charge by the electric field, assuming the trajectory z(t)=vt, as mentioned above. In this connection, it should be noted that the work done by a conservative force F(r, t) on a particle moving along a trajectory r(t) is simply given by

Δϵ=∫dt F(r(t),t)·v(t).

Therefore, the envelope wave function of the post-interaction electron can be written in the form

ϕ(z,t)=ϕ₀(z,t)e^{iφ}exp[i(Δϵ/ℏ)(z/v−t)]. (14)

Thus, the wave function in Eq. (14) is the incident one multiplied by an irrelevant phase factor e^{iφ} as well as by a plane wave exp[i(Δϵ/ℏ)(z/v−t)] representing a rigid energy shift by Δϵ (and a corresponding change in momentum by Δϵ/v within the nonrecoil approximation). Corrections of higher order terms in the aforementioned Taylor expansion may become relevant for electron wave packet durations similar to or larger than the field cycle.

Given that the electron energy spectrum observed in CDEM can be understood using the classical work done by the fields on a point charge, it is desired to provide a conceptually simpler and purely classical theory of CDEM. The classical theory amounts to (1) calculating the EM fields that act on the impinging electrons (this step is shared with the quantum theory), (2) calculating the classical work done on the electron, and (3) averaging over the initial electron distribution to get the statistics of energy loss that is experimentally probed. For the latter, the distribution refers to the electron pulse duration, which determines a variance in the electron arrival time, as well as the electron energy width, which broadens the measured energy spectrum.

In order to evaluate the electron energy shift in the classical limit, the electric and magnetic fields are to be first found resulting from the above potentials:

$$\begin{matrix}E = - ∇ Φ - \frac{\partial A}{\partial t} , & B = ∇ \times A .\end{matrix} \qquad ( 15 )$$

Next, the Lorentz force generated by the fields is calculated:

F=−e(E+v×B). (16)

Defining the electron trajectory along z as

s(t)=z₀+v(−Δt), (17)

the mean electron energy shift is then given by:

Δϵ(Δt)=∫ₜ_{ᵢ}^{L}^{_{f}}F·vdt=∫ₛ_{ᵢ}^{s}^{_{f}}F_{z}ds, (18)

where in the rightmost expression, the paraxiality assumption has been applied, implying that the electron velocity is directed exclusively along z. Moreover, under the quasi-static approximation, the magnetic field term in the Lorentz force can be neglected. For instance, in the experiment conducted by the inventors, this approximation is justified because the electron distance from the crystal is considerably smaller than the THz wavelength (x_{electron}≅10 μm<<λ_{THz}≅600 μm). Therefore, equations (15) and (16) become:

$$\begin{matrix}{F}_{z} = - e {E}_{z} , & {E}_{z} = - \frac{\partial Φ}{\partial z} - \frac{\partial {A}_{z}}{\partial t}\end{matrix} . \qquad ( 19 )$$

In the final step of the calculation, the mean electron energy shift Δϵ (Δt) is represented in energy-shift and time-delay space using a sum of delta functions:

$$Δℰ ( Δ t , ℰ ) = {\sum }_{Δ {t}_{i}} δ ( Δ t - Δ {t}_{i} , ℰ - Δℰ ( Δ {t}_{i} ) ) . \qquad ( 20 )$$

This expression is then convoluted with a kernel in two-dimensional energy-shift and time-delay space, in a similar manner to the aforementioned quantum theory, thus reproducing the EELS spectra observed in the experiment.

In the following, CDEM is compared to other regimes of electron-field interactions.

In general, there are three major regimes of interaction that prove to be important when considering free-electron interactions with classical external electromagnetic fields. These regimes are classified according to the duration of the field cycle τ_{EM} relative to the electron pulse duration and the electron-field interaction duration τₑ≤τᵢₙₜ (τᵢₙₜ is the ratio of the interaction length to the electron velocity,

$$\frac{L}{v} ) :$$

(1) τ_{EM}<<τₑ: This regime occurs in the extreme case of optical and higher frequency fields (field cycle τ_{EM}˜0.1-10 fs and even below), where the field cycle duration is much shorter than the electron pulse duration (e.g., τₑ˜350 fs in our setup). The difference in timescales causes each electron to experience many field cycles. The resulting electron energy spectrum is then similar to photon-induced near-field electron microscopy (PINEM), which includes multiple ho-spaced energy peaks, each of them with a probability corresponding to the emission or absorption of a given number of photon quanta by the electron. Notably, this result can only be accommodated by a quantum mechanical treatment of the free-electron wave function.

(2) τₑ, τᵢₙₜ<<τ_{EM}: In the opposite extreme, the field cycle is much longer than both the electron pulse duration and the time taken by that electron to traverse the region of interaction. Consequently, each electron experiences a time-independent field and, hence, undergoes no energy shift (since such fields are conservative). This field can however cause the electron to undergo elastic scattering, changing the electron transverse momentum, as in deflectometry measurements, which can be treated classically. This regime also encompasses electron holography and Lorentz microscopy, where only the electron phase (rather than its amplitude or energy) is altered by the (effectively DC) fields.

(3) Describing all the intermediate regimes requires a general theory as explained above. One such regime is when the field cycle is longer than the electron pulse duration, but shorter than the interaction timescale. This is the regime in which CDEM occurs. For example, let us consider a field cycle of a few ps (i.e., in the THz region), which is longer than the electron pulse duration, but comparable or shorter than the time it takes the electron to traverse the region of interaction. The electron can be considered as a point particle, but experiences a time-varying field during its interaction (thus, non-conservative fields). Consequently, the overall acceleration and deceleration experienced by the electron does not average to zero, and the resulting electron spectrum can include net gain or loss of energy (i.e., it is strongly asymmetric). This is in contrast to the two other regimes, in which the energy shift averages to zero and the resulting electron energy spectrum is symmetric.

Let us consider the hydrodynamic model of the photo-Dember effect observed in the experiment conducted by the inventors. This model takes us from the pump laser intensity through the spatio-temporal current density distribution inside the InAs crystal, and finally to the electric potential outside the crystal.

The mobility difference between photo-excited electrons and holes in InAs, together with the boundary condition imposed by the sample edges, lead to the rapid formation of a macroscopic (micron scale) dipole inside the crystal upon laser excitation.

While the lower-mobility holes are bound to the surface, higher-mobility electrons are free to travel under the influence of drift and diffusion. This effect, known as the photo-Dember effect, involves the acceleration of charge carriers on a picosecond timescale and is therefore commonly used as a source of single-cycle THz radiation.

The experimental considerations are as follows: The sample is a p-type InAs bulk sample (dopant concentration of 10¹⁷ cm⁻³). An 800 nm, 50 fs FWHM laser pulse with a repetition rate of 1 MHz impinges on the sample face along the x coordinate—perpendicular to the surface. The laser pulse duration is negligible compared to the other time constants of the system. Immediately after the action of the laser pulse, the following density of photo-excited pairs in the semiconductor is obtained: In the normal direction x, an exponential profile n(x)=n_{exc}e^{-ax}, where n_{exc} is the number of excited pairs on the surface and α=7 μm⁻¹ is the absorption coefficient; and in the transverse direction (the yz plane), a 2D Gaussian profile that follows the laser spot (40 μm FWHM). Due to the sharp decay of the distribution in the normal direction x relative to the much smoother distribution in the transverse direction yz, the following approximations can be safely adopted: The charge dynamics inside the sample can be assumed to be one-dimensional (current density jₓ along x); and for the purpose of solving the charge dynamics, the geometry can be considered as a semi-infinite sample in the x axis, and infinite in the y and z axes.

The dynamics of the electron-hole distribution in the system can be described using the hydrodynamic model of the photo-Dember effect. Applying this model, the transient current density inside the sample is given by

$${j}_{x} ( r , t ) = e {n}_{e x c} I ( s ) {v}_{t}^{2} α {e}^{- α x} {e}^{- \frac{γ t}{2}} \frac{sin ω t}{ω} , \qquad ( 21 )$$

$$ω = \sqrt{{ω}_{0}^{2} - {ω}_{1}^{2} ( 1 - {e}^{- α x} ) ,}$$

$${ω}_{0} = \sqrt{\frac{{e}^{2}}{ε} ( \frac{{n}_{e x c} I ( s )}{{m}^{*}} + \frac{{n}_{e q}}{{m}_{e q}} ) - \frac{{γ}^{2}}{4} ,} \qquad {ω}_{1} = \sqrt{\frac{{e}^{2}}{ε} \frac{{n}_{e x c} I ( s )}{{m}^{*}} .}$$

Here, vₜ²=vₜₑ²−vₜₕ² is the difference of the squares of the thermal velocities for electrons and holes, γ is the momentum relaxation rate associated with collisions inside the sample, neg is the concentration of equilibrium charges in the semiconductor (in this case, n_{eg} is the doping concentration), meg is the effective mass of equilibrium charges (here, n_{eq}=mₕ), and

$${m}^{*} = \frac{{m}_{e} {m}_{h}}{{m}_{e} + {m}_{h}}$$

with mₑ and mₕ denoting the effective masses of electrons and holes, respectively. Also, I(s) is the transverse laser-intensity profile (a dimensionless function) in the yz plane, while s is a transverse yz-plane coordinate, s=yŷ+zź.

Now the resulting potential is evaluated, noting that only E_{z} can change the electron energy (due to the paraxial approximation, as discussed in the CDEM theory above). Adopting the Lorenz gauge, the following formulae can be used to find the potentials:

$$\begin{matrix}A ( r , t ) = \frac{{μ}_{0}}{4 π} \int \frac{j ( {r}^{′} , {t}_{r} )}{\vert r - {r}^{′} \vert} {d}^{3} {r}^{′} , \\ Φ ( r , t ) = \frac{1}{4 {πε}_{0}} \int \frac{ρ ( {r}^{′} , {t}_{r} )}{\vert r - {r}^{′} \vert} {d}^{3} {r}^{′} ,\end{matrix} \qquad ( 22 )$$

where the retarded time is used, defined by

$${t}_{r} = t - \frac{\sqrt{{( x - {x}^{′} )}^{2} + {( y - {y}^{′} )}^{2} + {( z - {z}^{′} )}^{2}}}{c} . \qquad ( 23 )$$

According to these expressions, A_{z}=0 since j_{z}=0, and thus,

$${E}_{z} = - \frac{\partial Φ}{\partial z} - \frac{\partial {A}_{z}}{\partial t} = - \frac{\partial Φ}{\partial z} . \qquad ( 24 )$$

The next step is to find the charge density ρ. Neglecting band bending near the crystal edges, before the interaction there is a constant and uniform charge density ρ₀=en_{eq} across the crystal. To find the charge density after the interaction, the continuity equation is invoked:

$$\frac{\partial ρ ( r , t )}{\partial t} + \frac{\partial {j}_{x} ( r , t )}{\partial x} = 0 , \qquad ( 25 )$$

and hence,

$$ρ ( r , t ) = {ρ}_{0} - {\int }_{0}^{t} \frac{\partial {j}_{x} ( r , τ )}{\partial x} d τ . \qquad ( 26 )$$

The constant part ρ₀ can be neglected because it does not create any energy gain or loss. Also, the boundary condition jₓ(x<0, y,z,t)=0 is to be considered. Therefore, a surface charge density σ on the boundary is given by

σ(y,z,t)=−∫₀^{t}jx(x=0,y,z,t)dτ. (27)

Now, the scalar potential can be found:

$$Φ ( r , t ) = \frac{1}{4 {πε}_{0}} ( \int \frac{- {\int }_{0}^{t} \frac{\partial {j}_{x} ( {r}^{′} , τ )}{\partial {x}^{′}} d τ}{\vert r - {r}^{′} \vert} {d}^{3} {r}^{′} + \int \frac{- {\int }_{0}^{t} {j}_{x} ( {x}^{′} = 0 , {y}^{′} , {z}^{′} , τ )}{\vert r - {s}^{′} \vert} {ds}^{′} ) , \qquad ( 28 )$$

$$Φ ( r , t ) = \frac{- 1}{4 {πε}_{0}} ( \int \frac{{\int }_{0}^{t} \frac{\partial {j}_{x} ( {r}^{′} , τ )}{\partial {x}^{′}} d τ {dx}^{′} {dy}^{′} {dz}^{′}}{\sqrt{{( x - {x}^{′} )}^{2} + {( y - {y}^{′} )}^{2} + {( z - {z}^{′} )}^{2}}} + \int \frac{{\int }_{0}^{t} {j}_{x} ( {x}^{′} = 0 , {y}^{′} , {z}^{′} , τ ) {dy}^{′} {dz}^{′}}{\sqrt{{( x - 0 )}^{2} + {( y - {y}^{′} )}^{2} + {( z - {z}^{′} )}^{2}}} ) .$$

Integrating by parts, the following is obtained:

$$Φ ( r , t ) = \frac{1}{4 {πε}_{0}} ( \int {dy}^{′} {dz}^{′} {\int }_{0}^{+ ∞} {dx}^{′} \frac{{\int }_{0}^{t} {j}_{x} ( {r}^{′} , τ ) d τ \cdot ( {x}^{′} - x )}{{( {( x - {x}^{′} )}^{2} + {( y - {y}^{′} )}^{2} + {( z - {z}^{′} )}^{2} )}^{\frac{3}{2}}} ) , \qquad ( 29 )$$

where jₓ is taken from the hydrodynamic model of the photo-Dember effect (Eq. (21)):

$${\int }_{0}^{t} {j}_{x} ( {r}^{′} , τ ) d τ = - \frac{e {n}_{e x c} I ( s ) {v}_{t}^{2} α {e}^{- α {x}^{′}}}{ω ( {γ}^{2} + 4 {ω}^{2} )} ( 4 ω cos ω t + 2 γ sin ω t ) {e}^{- \frac{γ t}{2}} . \qquad ( 30 )$$

Through Eqs. (8) and (11), the calculated scalar potential is then used to evaluate the evolution of the electron wave function following the interaction with the field, and finally obtain the resulting electron spectrum.

Thus, the present invention provides a novel modified electron beam column (generally, charged particles' beam column) with the improved energy resolution. As described above, this is achieved by selecting the spatio-temporal shape of a pulse of THz radiation to compress the energy-width of the electron beam and spatial distribution of electron beam. The optimal control/selection of the parameters of the THz radiation to provide the desired/optimal spatio-temporal shape is enabled because the THz radiation emitter(s) is/are located inside the electron beam column in the vicinity of the general propagation path of the electron beam towards a sample plane. Also, using a THz emitter of the type that does not require any aperture/resonator is preferred, and provides for obtaining the electron beam compression effect tens of microns away from the emitter.

In the specific example of UTEM beam column, laser operational wavelength of 800 nm was used, with 50 fs pulse duration, operating at 1 MHz repetition rate. The 1 nJ laser peak energy provided compression factor of 3. Fitting data to simulation provided a peak THz field of ˜4.10⁴V/m. The inventors have shown that the efficiency of the system operation utilizing the internal THz radiation emitter(s) is of at least 3 orders of magnitude higher than a similar system with external THz source, and the efficiency can be increased even more since the laser energy required to obtain roughly the same compression is significantly lower. Moreover, the higher the required power of the THz radiation, the stronger pump-laser is needed to pump the THz generation setup, which would lead to a limitation on the system repetition rate (to avoid heating).

The achieved compression factor of ˜3 in electron energy spread described above might not be sufficient to compete with high-end conventional HR-TEMs. The state-of-the-art slit-based monochromators (MCs) can provide electron energy spread ΔE on the order of several meV (relative to ΔE=300 meV in electron microscopes w/o MCs). This is a reduction of ˜x20 in the energy spread. However, this improvement comes with a penalty: severely attenuating the electron flux by a factor of x20 and above. This attenuation degrades the performance of HR-TEMs. In particular, flux attenuation is a major limitation in UTEM applications, which suffer from low flux a priori due to the pulsed nature of their operation, thereby preventing the application of conventional MCs to UTEM. In addition, slit-based MCs are expensive and require extremely stabilized power sources, which highly complicates their deployment and limits the integration time due to drift phenomena. Moreover, such slit-based MCs introduce spherical aberrations that fundamentally limit image acquisition.

As already noted above, the beam shaping unit (104 in FIG. 2) may be configured to define an array of interaction regions arranged in a spaced-apart relationship along the general propagation path of electrons. To this end, the THz source/generator may include an array of THz generators/emitters each configured and operable to manipulate the electron pulse at a respective interaction region while the electron pulse propagates inside the microscope. Thus, the electron pulse is affected by cascade-type interactions with the THz radiation.

FIG. 9 shows an electron microscope system 100 which is configured generally similar to system of FIG. 2, as well as more specific example of FIGS. 3A-3B, namely includes an electron beam column 102 and an electron beam shaping unit 104, where the electron beam column 102 includes an electron beam source 101, generating an electron beam propagating along a general propagation path GPP towards a specimen (specimen plane), and detector(s) 105 for detecting electrons resulting from the electron beam interaction with the specimen. The electron beam shaping unit 104 (monochromator MC) includes a THz radiation generator 106 including semiconductor structure (e.g., an InAs crystal) 10 excitable by laser pulse 12 to generate THz pulses which propagate in free space outside the crystal 10 and interact with the electron beam propagating along the general propagation path GPP. In the example of FIG. 9, the electron beam shaping unit 104 is configured as a multi-interaction monochromator (MC) defining an array of interaction regions 15 arranged in a spaced-apart relationship along the general propagation path GPP. This is implemented in the present example by providing a reflector 16 extending along and being spaced-apart from the general propagation path GPP.

The exciting laser beam 12 interacts with a first location of the crystal, and while causing generation of the THz pulse which propagates to the first interaction region 15, is reflected from the crystal and propagates to a first location on the reflector 16. The laser beam is reflected from said first location of the reflector towards a second location of the crystal, where the THz pulse is generated propagating to the second interaction region 15, and the laser beam is again reflected from the crystal to a second location on the reflector 16 and so on.

Thus, this configuration provides an array of sequentially created THz emitters/generators (an array of sequentially excited locations along the crystal) and a corresponding array of sequentially operated interaction regions 15 causing multiple interactions of the electrons with THz radiation. The input laser pulse is used multiple times resulting in multiple interactions of the electron with THz radiation that is generated each time the laser pulse hits the InAs crystal. It should be noted that considering the use of electron pre-shaping stage as a first interaction, the above described multiple interactions are successive second interactions.

The incidence angle of the laser is tuned such that the electron velocity matches exactly the laser's effective propagation. With each time the laser and electron pulse interact, the electron pulse is additionally compressed. A compression factor of 20 can be obtained after 3 such interactions.

Thus, the plurality of spaced-apart interaction regions along the general propagation path of the charged particles beam may be formed by multiple reflections of a laser source from a reflector placed in a vicinity of, e.g., the InAs crystal, thereby forming an array of the high-frequency electromagnetic radiation emitters. Such multi-interaction monochromator (MC) can be used in HR-TEM applications enabling an increased compression of the electron energy.

1. A charged particles beam column for inspecting a sample in a sample plane, the charged particles beam column comprising: a charged particles source generating a charged particles beam propagating along a general propagation path towards the sample plane; and at least one charged particles beam shaping unit comprising at least one high-frequency electromagnetic radiation generator located in a vicinity of said general propagation path of the charged particles beam and controllably operated to perform synchronized generation of said high-frequency electromagnetic radiation towards at least one interaction region in said general propagation path, to cause interaction between said radiation and the charged particles, thereby directly affecting energy properties of the charged particles passing through said at least one interaction region in the general propagation path and directly affecting spectral resolution of the charged particles beam at said sample plane.

2. The charged particles beam column according to claim 1, wherein said charged particles beam is an electron beam.

3. The charged particles beam column according to claim 1, wherein the high-frequency electromagnetic radiation generator is configured to produce pulsed THz radiation.

4. The charged particles beam column according to claim 1, wherein a high frequency electromagnetic field produced by said radiation is configured to compress energy-width of the charged particles beam.

5. The charged particles beam column according to claim 4, wherein a spatio-temporal shape of a pulse of the high-frequency electromagnetic radiation is configured to compress the energy-width of the charged particles beam.

6. The charged particles beam column according to claim 4, wherein a spatio-temporal shape of a pulse of the high-frequency electromagnetic radiation is configured to reduce spatial distribution of the charged particles beam,

7. The charged particles beam column according to claim 5, wherein a spatio-temporal shape of a pulse of the high-frequency electromagnetic radiation is configured to reduce spatial distribution of the charged particles beam,

8. The charged particles beam column according to claim 1, wherein said radiation is a pulsed radiation, and a time delay between a time of the generation of the radiation pulse and a time of arrival of the charged particles to the interaction region are controlled to provide temporal overlap between the charged particle and said radiation in the interaction region.

9. The charged particles beam column according to claim 1, wherein the at least one high-frequency electromagnetic radiation emitter is configured to generate said radiation with varying efficiency.

10. The charged particles beam column according to claim 9, wherein the at least one high-frequency electromagnetic radiation emitter comprises a structure configured to generate said radiation based on at least one of the following effects: photo-Dember effect, optical rectification effect.

11. The charged particles beam column according to claim 1, wherein the high frequency radiation generator comprises an array of the high-frequency electromagnetic radiation emitters producing said radiation towards an array of spaced-apart interaction regions spaced-apart along the general propagation path of the charged particles beam.

12. The charged particles beam column according to claim 11, wherein the charged particles beam shaping unit comprises a reflector extending along the general propagation path and being spaced-apart from the general propagation path, said array of the high-frequency electromagnetic radiation emitters being defined by an array of locations of said high frequency radiation generator arranged in a spaced-apart relationship along the general propagation path, said locations being sequentially excited to generate the high frequency radiation by sequential reflections of exciting radiation from an array of spaced-apart locations along said reflector, thereby providing the array of said spaced-apart interaction regions through which the electron beam successively passes while propagating along the general propagation path.

13. The charged particles beam column according to claim 1, further comprising a pre-shaping assembly at output of the charged particles beam source, said pre-shaping assembly being configured and operable to tune the charged particles beam flow having initial continuous wave form into pulses propagating towards said at least one interaction region.

14. The charged particles beam column according to claim 1, configured as a scanning electron microscope (SEM).

15. The charged particles beam column according to claim 1, configured as transmission electron microscope (TEM).

16. The charged particles beam column according to claim 15, configured as Ultrafast Transmission Electron Microscope (UTEM).

17. A monochromator configured for integration in a charged particles beam column for inspecting a sample in a sample plane, the monochromator comprising at least one charged particles beam shaping unit comprising at least one high-frequency electromagnetic radiation generator located in a vicinity of a general propagation path of a charged particles beam emitted by a charged particles source, each of said at least one high-frequency electromagnetic radiation generator being configured and controllably operated to perform synchronized generation of said high-frequency electromagnetic radiation towards an interaction region in said general propagation path, to cause interaction between said radiation and the charged particles, thereby directly affecting energy properties of the charged particles passing through said at least one interaction region in the general propagation path and directly affecting spectral resolution of the charged particles beam at said sample plane.

18. A method for controlling inspection of a sample by interaction with a charged particles beam, the method comprising: tuning a charged particles beam flow having initial continuous wave form into pulses by interaction of said charged particles beam with RF radiation in a first interaction within a general propagation path of the charged particles beam towards the sample, and affecting energy properties of the pulses of the charged particles beam by interaction with high-frequency electromagnetic radiation in at least one second interaction region within said general propagation path downstream of said first interaction region with respect to a direction of propagation of the charged particles beam along said path towards the sample, thereby directly affecting spectral resolution of the charged particles beam at the sample location.
